(19) United States
(12) Patent Application Publication
(10) Pub. No.: US 2023/0039391 A1
(43) Pub. Date: Feb. 9, 2023

(54) DISPLAY PANEL AND DISPLAY DEVICE INCLUDING THE SAME

(71) Applicant: LG DISPLAY CO., LTD., Seoul (KR)

(72) Inventors: Jungchul KIM, Paju-si (KR); Youngsik KIM, Jinju-si (KR); Minsu KIM, Goyang-si (KR); Yongmin HA, Seoul (KR); Hanwook HWANG, Paju-si (KR)

(73) Assignee: LG DISPLAY CO., LTD., Seoul (KR)

(21) Appl. No.: 17/870,007

(22) Filed: Jul. 21, 2022

(30) Foreign Application Priority Data
Aug. 3, 2021 (KR) 10-2021-0102076

(51) Int. Cl. H01L 27/32

(52) U.S. Cl. CPC H01L 27/3276; H01L 27/3218

(57) ABSTRACT

A display panel capable of reducing a width of a bezel of an area around a hole and a display device including the panel are disclosed. The display panel having the hole defined therein includes a first pixel array including source lines and sub-pixels; a bezel defined around the hole and at least one of the source lines of the first pixel array extends in and along the bezel; and a second pixel array including sub-pixels and the at least one source line extending along the bezel and to the second pixel array.

### CROSS-REFERENCE TO RELATED APPLICATION

This application claims the priority of Korean Patent Application No. 10-2021-0102076 filed on Aug. 3, 2021, which is hereby incorporated by reference in its entirety.

### BACKGROUND

### Field of the Disclosure

The present disclosure relates to a display panel and a display device including the same, and more particularly, to a display panel capable of reducing a bezel width of an area around a hole and a display device including the same.

### Description of the Background

As the information society develops, demand for display devices that display images is increasing. Thus, various types of display devices such as liquid crystal display devices and organic light-emitting display devices are being used.

Among these display devices, the organic light-emitting display device includes an organic light-emitting diode that emits light by itself, and thus has high response speed, high contrast ratio, high light-emitting efficiency, high luminance and wide field of view (FOV).

A display device includes a display panel, a source driver, a gate driver and a timing controller. The display panel includes a plurality of gate lines, a plurality of source lines and a plurality of sub-pixels.

A hole may be formed in a partial area of the display panel. The gate line and the source line may be discontinuous due to the hole. Thus, the source line is disposed in a bezel of an area around the hole. This source line can increase a bezel width of the area around the hole such that the image quality can be deteriorated.

The above information disclosed in this Background section is only for enhancement of understanding of the background of the described technology and therefore it may contain information that does not form prior art that is already known to a person of ordinary skill in the art.

### SUMMARY

Accordingly, the present disclosure is directed to a display panel and a display device including the same that substantially obviate one or more of problems due to limitations and disadvantages described above.

More specifically, the present disclosure is to provide a display panel that can reduce the bezel width of the area around the hole.

The present disclosure is also to provide a display panel capable of reducing the bezel width of the area around the hole and a display device including the same.

Further, the present disclosure is to provide a display panel capable of reducing the bezel width of the area around the hole to maintain image quality and a display device including the same.

The present disclosure is not limited to the above-mentioned purpose. Other features and advantages of the present disclosure that are not mentioned may be understood based on following descriptions, and may be more clearly understood based on aspects of the present disclosure. Further, it will be easily understood that the purposes and advantages of the present disclosure may be realized using means shown in the claims and combinations thereof.

A first aspect of the present disclosure provides a display panel having a hole defined therein, the display panel comprising: a first pixel array including source lines and sub-pixels; a bezel of an area around the hole, wherein at least one of the source lines of the first pixel array extends in and along the bezel; and a second pixel array including sub-pixels and the at least one source line extending along and in the bezel of the area around the hole and into the second pixel array.

In one implementation of the first aspect, a number of the at least one source line extending in and along the bezel of the area around the hole is smaller than a number of the source lines of the first pixel array.

In one implementation of the first aspect, in the second pixel array, the at least one source line shares sub-pixels in different columns.

In one implementation of the first aspect, in the second pixel array, the at least one source line shares sub-pixels corresponding to the same color among sub-pixels in different columns.

In one implementation of the first aspect, at least two of the source lines of the first pixel array extend in and along the bezel of the area around the hole.

In one implementation of the first aspect, at least two of the source lines of the first pixel array includes: a first source line corresponding to a blue color, a second source line corresponding to a green color, a third source line corresponding to a red color, and a fourth source line corresponding to a green color.

In one implementation of the first aspect, the first source line is connected to sub-pixels corresponding to the blue color of a first column and a fifth column in the second pixel array, the second source line is connected to sub-pixels corresponding to the green color of a second column and a sixth column in the second pixel array, the third source line is connected to sub-pixels corresponding to the red color of a third column and a seventh column in the second pixel array, and the fourth source line is connected to sub-pixels corresponding to the green color of a fourth column and an eighth column in the second pixel array.

In one implementation of the first aspect, in the first pixel array, the source lines extend in a vertical direction, wherein the bezel of the area around the hole is disposed between the first pixel array and the second pixel array, wherein the at least one of the source lines of the first pixel array extends along and in the bezel of the area around the hole.

A second aspect of the present disclosure provides a display device comprising: a display panel having a hole defined therein; and a source driver for providing a source signal to the display panel, wherein the display panel includes: a first pixel array including source lines for transmitting the source signal and sub-pixels for emitting light based on the source signal; a bezel of an area around the hole, wherein at least one of the source lines of the first pixel array extends in and along the bezel; and a second pixel array including sub-pixels and the at least one source line extending along and in the bezel of the area around the hole and into the second pixel array.

In one implementation of the second aspect, a number of the at least one source line extending in and along the bezel of the area around the hole is smaller than a number of the source lines of the first pixel array.

In one implementation of the second aspect, in the second pixel array, the at least one source line shares sub-pixels in different columns.

In one implementation of the second aspect, in the second pixel array, the at least one source line shares sub-pixels corresponding to the same color among sub-pixels in different columns.

In one implementation of the second aspect, at least two of the source lines of the first pixel array extend in and along the bezel of the area around the hole.

In one implementation of the second aspect, at least two of the source lines of the first pixel array includes: a first source line corresponding to a blue color, a second source line corresponding to a green color, a third source line corresponding to a red color, and a fourth source line corresponding to a green color.

In one implementation of the second aspect, the first source line is connected to sub-pixels corresponding to the blue color of a first column and a fifth column in the second pixel array, the second source line is connected to sub-pixels corresponding to the green color of a second column and a sixth column in the second pixel array, the third source line is connected to sub-pixels corresponding to the red color of a third column and a seventh column in the second pixel array, and the fourth source line is connected to sub-pixels corresponding to the green color of a fourth column and an eighth column in the second pixel array.

A third aspect of the present disclosure provides a display panel having a hole defined therein, the display panel comprising: a first pixel array; a second pixel array; and a bezel of an area around the hole, wherein the bezel is formed between the first pixel array and the second pixel array, wherein at least one of source lines disposed in the first pixel array and extending in a vertical direction extends along and in the bezel of the area around the hole.

In one implementation of the third aspect, the at least one source line extending in and along the bezel of the area around the hole extends into the second pixel array in the vertical direction.

In one implementation of the third aspect, a number of source lines disposed in the second pixel array is smaller than a number of the source lines disposed in the first pixel array.

In one implementation of the third aspect, in the second pixel array, each of the at least one source line shares sub-pixels in different columns.

In one implementation of the third aspect, in the second pixel array, each of the at least one source line shares sub-pixels corresponding to the same color among sub-pixels in different columns.

According to an aspect, the number of source lines disposed in the bezel of the area around the hole may be reduced such that the bezel width of the area around the hole may be reduced.

Further, the source lines extending from the bezel of the area around the hole may share sub-pixels of different columns such that image quality may be maintained.

Further, the bezel width of the area around the hole may be reduced to prevent immersion into a displayed image from being deteriorated due to the bezel width.

Effects of the present disclosure are not limited to the above-mentioned effects, and other effects as not mentioned will be clearly understood by those skilled in the art from following descriptions.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a display device including a display panel according to the present disclosure;

FIG. 2 is an enlarged view of area 'A' around a hole shown in FIG. 1;

FIG. 3 is a cross-sectional view taken along line I-I' in FIG. 2;

FIG. 4 is a view showing a portion of a display panel in an area around a hole shown in FIG. 1;

FIG. 5 is a diagram showing an enlarged example of 'B' area and 'C' area of FIG. 4;

FIG. 6 is a diagram showing another enlarged example of 'B' area and 'C' area of FIG. 4; and

FIG. 7 is a circuit diagram of a display panel corresponding to the 'C' area of FIG. 4.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed below, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the aspects of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes "a" and "an" are intended to include the plural constitutes as well, unless the context clearly indicates otherwise. It will be further understood that the terms "comprise", "including", "include", and "including" when used in this specification, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of the associated listed items. Expression such as "at least one of" when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present "on" a second element or layer, the first element may be disposed directly on the second element or may be disposed indirectly on the second element with a third element or layer being disposed between the first and second elements or layers. It will be understood that when an element or layer is referred to as being "connected to", or "coupled to" another element or layer, it may be directly on, connected to, or coupled to the other element or layer, or one or more intervening elements or layers may be present. In addition, it will also be understood that when an element or layer is referred to as being "between" two elements or layers, it may be the only element or layer between the two elements or layers, or one or more intervening elements or layers may also be present.

Further, as used herein, when a layer, film, region, plate, or the like may be disposed "on" or "on a top" of another layer, film, region, plate, or the like, the former may directly contact the latter or still another layer, film, region, plate, or the like may be disposed between the former and the latter. As used herein, when a layer, film, region, plate, or the like is directly disposed "on" or "on a top" of another layer, film, region, plate, or the like, the former directly contacts the latter and still another layer, film, region, plate, or the like is not disposed between the former and the latter. Further, as used herein, when a layer, film, region, plate, or the like may be disposed "below" or "under" another layer, film, region, plate, or the like, the former may directly contact the latter or still another layer, film, region, plate, or the like may be disposed between the former and the latter. As used herein, when a layer, film, region, plate, or the like is directly disposed "below" or "under" another layer, film, region, plate, or the like, the former directly contacts the latter and still another layer, film, region, plate, or the like is not disposed between the former and the latter.

In descriptions of temporal relationships, for example, temporal precedent relationships between two events such as "after", "subsequent to", "before", etc., another event may occur therebetween unless "directly after", "directly subsequent" or "directly before" is not indicated.

It will be understood that, although the terms "first", "second", "third", and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

It will be understood that when an element or layer is referred to as being "connected to", or "coupled to" another element or layer, it may be directly on, connected to, or coupled to the other element or layer, or one or more intervening elements or layers may be present. In addition, it will also be understood that when an element or layer is referred to as being "between" two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel capable of reducing a bezel width of an area around a hole and a display device including the same are disclosed.

As used herein, a top and a bottom are related to a cross sectional view of a display device, while upper, lower, left and right are related to a plan view of the display device.

As used therein, a vertical direction may be defined as the Y-axis direction in the plan view of the display device, while a horizontal direction may be defined as the X-axis direction in the plan view of the display device.

As used herein, an area around a hole may be defined as an area disposed around a hole defined in the display panel.

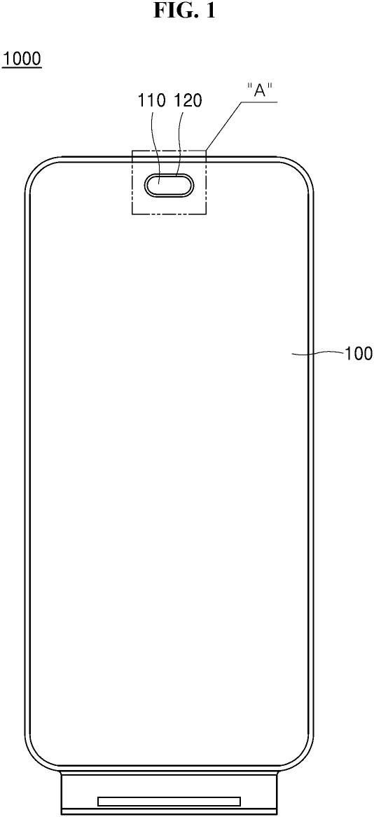

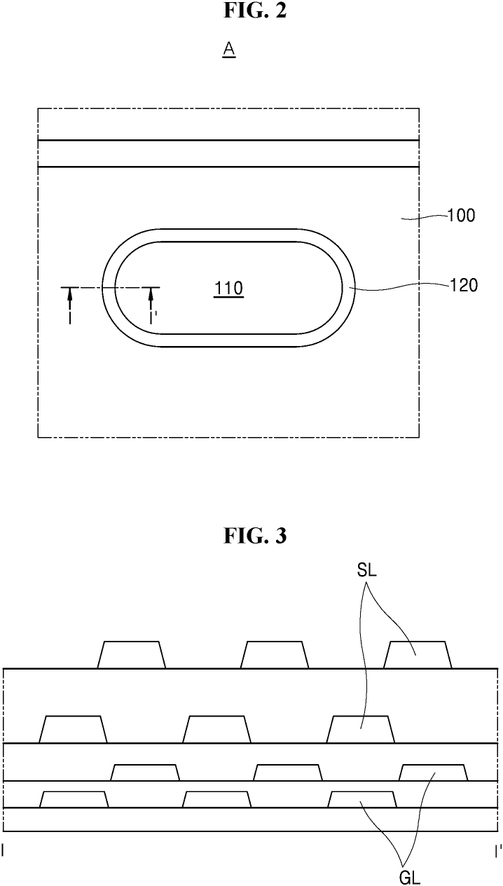

FIG. 1 is a plan view of a display device 1000 including a display panel 100 according to the present disclosure. FIG. 2 is an enlarged view of area 'A' around a hole 110 shown in FIG. 1. FIG. 3 is a cross-sectional view taken along line I-I' in FIG. 2.

Referring to FIG. 1 to FIG. 3, the display device 1000 includes the display panel 100. A plurality of gate lines GL, a plurality of source lines SL and a plurality of sub-pixels R, G, and B may be disposed in the display panel 100.

In one example, in the display panel 100, sub-pixels R, G, and B may be respectively disposed in areas where the plurality of source lines SL and the plurality of gate lines GL intersect each other. The plurality of sub-pixels R, G, and B constitute a pixel array. The pixel array may include a sub-pixel R corresponding to a red color, a sub-pixel G corresponding to a green color, and a sub-pixel B corresponding to a blue color.

Moreover, the display device 1000 may further include a source driver, a gate driver and a timing controller.

The source driver may provide a source signal to the source line SL of the display panel 100, and the gate driver may provide a gate signal to the gate line GL of the display panel 100. Moreover, the timing controller may provide image data and control data to the source driver, and may provide a timing control signal to the gate driver.

The hole 110 may be formed in a partial area of the display panel 100. In one example, when the display panel 100 is applied to a smart phone, a speaker module or a camera module may be disposed under the hole 110. In the display panel 100 in which the hole 110 is formed, the gate line GL, the source line SL and/or other signal lines may be discontinuous due to the hole 110.

In the display panel 100 having the hole, the gate line GL extending in the horizontal direction and transmitting the gate signal of the gate driver, and the source line SL extending in the vertical direction and transmitting the source signal of the source driver may bypass the hole 110. Alternatively, the gate line GL may extend in the vertical direction, the source line SL may extend in the horizontal direction, and one or both of the gate line GL and the source line SL may bypass the hole 110 when respective drivers are disposed at one side or end of the display panel 100. Similarly, various other signal lines extending in the vertical/horizontal direction may also bypass the hole 110 according to the arrangement of respective drivers for providing signals to the lines.

When, in this way, the signal line is designed to bypass the hole 110, a non-light-emitting area may be increased due to various signal lines extending in the area around the hole 110. In particular, an organic light-emitting display device includes a compensation circuit to compensate for deterioration of the pixels. Thus, there are signal lines that transmit a large number of signals, such that a width of a bezel 120 defined in the area around the hole 110 may be further increased.

Moreover, in the display panel 100 in which the hole 110 is formed, the gate line GL and the source line SL may be discontinuous due to the hole 110. To solve this problem, in accordance with the present disclosure, some of the source lines SL extending in the vertical direction in the pixel array may extend in the vertical direction along and in the bezel 120 defined in the area around the hole 110.

The arrangement of the source line according to the present disclosure seeks to prevent the image quality from being deteriorated due to the increase in the width of the bezel 120 defined in the area around the hole 110.

Specifically, the present disclosure discloses a display panel in which the number of source lines is reduced by half in order to the reduce the bezel width defined in the area around the hole, thereby minimizing deterioration of the image quality, and a display device including the same.

In one example, ½ of the source lines extending in the vertical direction toward the hole of the display panel may be disposed in the bezel defined in the area around the hole, thereby preventing the bezel width from being increased.

Moreover, the source line extending in the vertical direction in and along the bezel defined in the area around the hole shares at least two or more sub-pixel columns, thereby preventing image quality deterioration.

In one example, one source line may share two sub-pixel columns. For example, a source line may share sub-pixel columns corresponding to a blue color. A source line may share sub-pixel columns corresponding to a green color. A source line may share sub-pixel columns corresponding to a red color.

The number of source lines disposed in the bezel defined in the area around the hole may be reduced by half to the reduce the bezel width around the hole such that the image quality may be maintained.

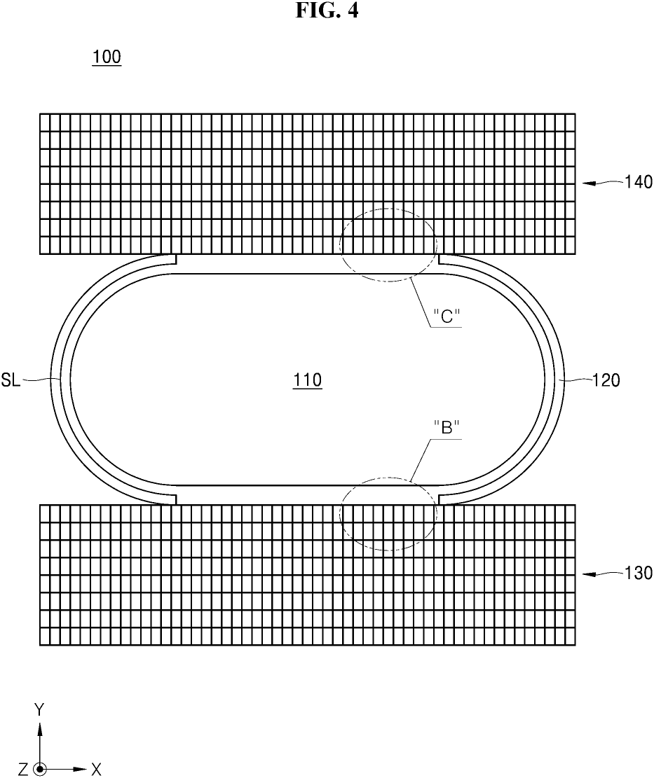

The embodiments of the present disclosure will be described with reference to FIG. 4 to FIG. 7 hereinafter, in which the supply line is shown and described as an example of various signal lines.

FIG. 4 is a view showing a portion of the display panel 100 in the area around the hole 110 shown in FIG. 1.

Referring to FIG. 4, the display panel 100 may include a first pixel array 130, the bezel 120 defined in the area around the hole, and a second pixel array 140, so that the first and second pixel arrays 130, 140 are separated by the bezel 120.

In accordance with the present disclosure, in a plan view as shown in FIG. 4, the first pixel array 130 may be located below (in the -Y-axis direction) the bezel 120 defined in the area around the hole. In the first pixel array 130, source lines extending in the vertical direction toward the bezel 120 defined in the area around the hole 110 and sub-pixels may be disposed. In this embodiment, the source driver is disposed at a lower end of the display panel 100.

In accordance with the present disclosure, in a plan view as shown in FIG. 4, the second pixel array 140 may be located above (in the +Y-axis direction) the bezel 120 defined in the area around the hole 110. In the second pixel array 140, at least one source line extending in the vertical direction from the bezel 120 defined in the area around the hole and sub-pixels may be disposed.

Some of the source lines SL extending in the vertical direction from the first pixel array 130 may extend along and in the bezel 120 defined in the area around the hole. Some source lines may extend in the vertical direction from the second pixel array 140.

In one example, in order to reduce the width of the bezel 120 defined in the area around hole 110, a half of the source lines of the first pixel array 130 may extend along the bezel 120, and a half of the source lines extending along the bezel 120 may extend in a vertical direction toward the second pixel array 140 and be disposed in the second pixel array 140.

A source line extending in the vertical direction along the bezel 120 defined in the area around the hole may share at least two or more sub-pixel columns in the second pixel array 140.

In one example, two sub-pixel columns may be connected to one source line. Sub-pixel columns corresponding to a blue color may be connected to a first source line, sub-pixel columns corresponding to a green color may be connected to a second source line, sub-pixel columns corresponding to a red color may be connected to a third source line, and sub-pixel columns corresponding to further green color may be connected to a fourth source line.

A half of the source lines disposed in the first pixel array 130 may be extend in and along the bezel 120 defined in the area around the hole to reduce the bezel width around the hole. The sub-pixel columns corresponding to the same color in the second pixel array 140 may be connected to one source line such that the image quality may be maintained.

In one example, the display device may include a liquid crystal panel or an organic light-emitting diode panel as the display panel 100. Among these display devices, the organic light-emitting display device includes an organic light-emitting diode that emits light by itself, and thus has high response speed, high contrast ratio, high light-emitting efficiency, high luminance and wide field of view (FOV). In the organic light-emitting display device, the pixel array of the display panel 100 may include a red color sub-pixel, a green color sub-pixel, and a blue color sub-pixel. Each sub-pixel may include a pixel circuit operating in response to the source signal provided from the source driver.

The pixel circuit of the sub-pixel may include a light-emitting element, a storage capacitor, a driving transistor, and a gate transistor. The driving transistor may provide a current corresponding to the source signal to the light-emitting element.

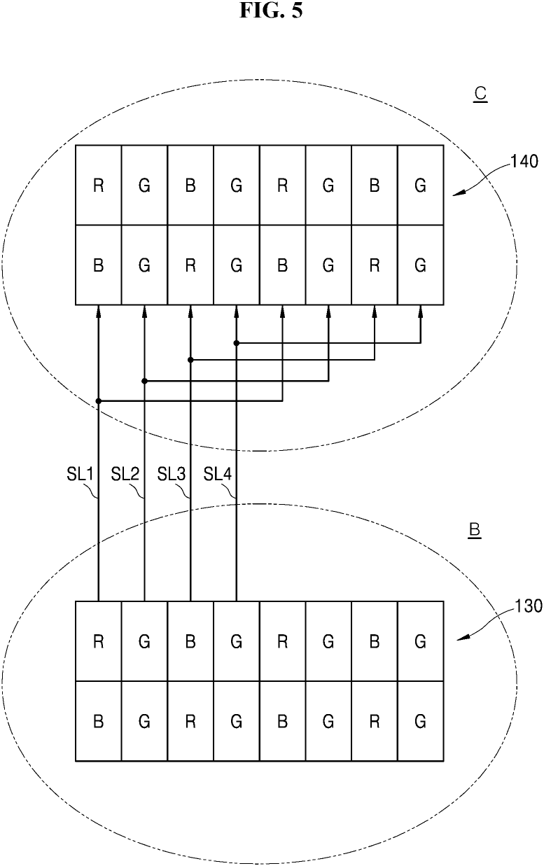

FIG. 5 is a diagram showing an enlarged example of 'B' area and 'C' area of FIG. 4.

Referring to FIG. 4 and FIG. 5, in a plan view, the first pixel array 130 may be located below (in the -Y-axis direction) the bezel 120 defined in the area around the hole 110. In the first pixel array 130, source lines extending in the vertical direction toward the bezel 120 defined in the area around the hole and sub-pixels may be disposed. In a plan view, the second pixel array 140 may be located above (in the +Y-axis direction) the bezel 120 defined in the area around the hole 110. In the second pixel array 140, at least one source line extending in the vertical direction from the bezel 120 defined in the area around the hole and sub-pixels may be disposed. The bezel 120 defined in the area around the hole 110 may be located between the first pixel array 130 and the second pixel array 140.

In FIG. 5, 'B' area includes a partial area of the first pixel array 130 and a partial area of the bezel 120, and 'C' area includes a partial area of the bezel 120 and a partial area of the second pixel array 140.

The first pixel array 130 includes source lines extending in the vertical direction, the gate lines extending in the horizontal direction, and sub-pixels R, G, and B respectively disposed in areas at which the source lines and the gate lines intersect with each other.

The source lines of the first pixel array 130 extends in the vertical direction toward the bezel 120 of the area around the hole. Some source lines SL1, SL2, SL3, and SL4 of the source lines extends in and along the bezel 120 defined in the area around the hole.

In one example, among the source lines of the first pixel array 130, a first source line SL1 corresponding to a first sub-pixel column, a second source line SL2 corresponding to a second sub-pixel column, a third source line SL3 corresponding to a third sub-pixel column, and a fourth source line SL4 corresponding to a fourth sub-pixel column may extend in an along the bezel 120 defined in the area around the hole.

The number of the source lines SL1, SL2, SL3, and SL4 extending in and the along the bezel 120 defined in the area around the hole may be smaller than the total number of source lines disposed in the first pixel array 130.

Moreover, the first source line SL1 to the fourth source line SL4 extending along and in the bezel 120 defined in the area around the hole may extend in the vertical direction and thus may be disposed in the second pixel array 140.

The second pixel array 140 includes the first source line SL1 to the fourth source line SL4 extending in the vertical direction, gate lines extending in the horizontal direction, and sub-pixels R, G, and B respectively disposed in areas where the first source line SL1 to the fourth source line SL4 and the gate lines intersect each other.

Each of the first source line SL1 to the fourth source line SL4 in the second pixel array 140 shares sub-pixels in different columns. In one example, in the second pixel array 140, each of the first source line SL1 to the fourth source line SL4 shares sub-pixels corresponding to the same color among sub-pixels in different columns.

Specifically, the source lines extending from the bezel 120 defined in the area around the hole to the second pixel array 140 may include the first source line SL1 corresponding to the blue color, the second source line SL2 corresponding to the green color, the third source line SL3 corresponding to the red color, and the fourth source line SL4 corresponding to the green color.

In the second pixel array 140, the first source line SL1 is connected to sub-pixels B of first and fifth columns corresponding to the blue color in the second pixel array 140. The second source line SL2 is connected to sub-pixels G of second and sixth columns corresponding to the green color. The third source line SL3 is connected to sub-pixels R of a third column and a seventh column corresponding to the red color. The fourth source line SL4 is connected to sub-pixels G of a fourth column and an eighth column corresponding to the green color.

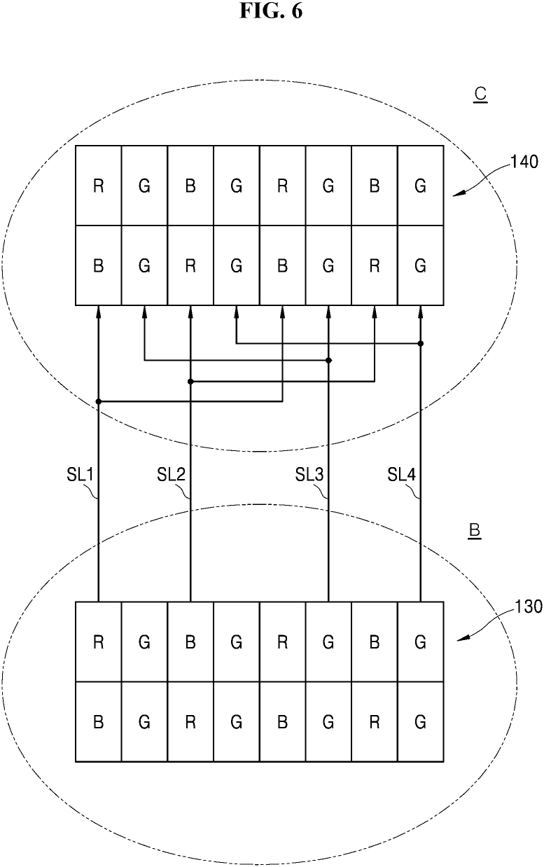

FIG. 6 is a diagram showing another enlarged example of 'B' area and 'C' area of FIG. 4.

In FIG. 6, 'B' area includes a partial area of the first pixel array 130 and a partial area of the bezel 120. 'C' area includes a partial area of the bezel 120 and a partial area of the second pixel array 140.

Referring to FIG. 4 and FIG. 6, in a plan view, the first pixel array 130 may be located below (in the -Y-axis direction) the bezel 120 defined in the area around the hole 110. In the first pixel array 130, source lines extending in the vertical direction toward the bezel 120 defined in the area around the hole and sub-pixels may be disposed.

In a plan view, the second pixel array 140 may be located above (in the +Y-axis direction) the bezel 120 defined in the area around the hole 110. In the second pixel array 140, at least one source line extending in the vertical direction from the bezel 120 defined in the area around the hole and sub-pixels may be disposed. The bezel 120 defined in the area around the hole may be located between the first pixel array 130 and the second pixel array 140.

The first pixel array 130 includes source lines extending in the vertical direction, the gate lines extending in the horizontal direction, and sub-pixels R, G, and B respectively disposed in areas at which the source lines and the gate lines intersect with each other.

The second pixel array 140 includes the first source line SL1 to the fourth source line SL4 extending in the vertical direction, gate lines extending in the horizontal direction, and sub-pixels R, G, and B respectively disposed in areas where the first source line SL1 to the fourth source line SL4 and the gate lines intersect each other.

The source lines of the first pixel array 130 extends in the vertical direction toward the bezel 120 defined in the area around the hole. Some source lines SL1, SL2, SL3, and SL4 of the source lines extends in and along the bezel 120 defined in the area around the hole.

In one example, among the source lines of the first pixel array 130, a first source line SL1 corresponding to a first sub-pixel column, a second source line SL2 corresponding to a third sub-pixel column, a third source line SL3 corresponding to a sixth sub-pixel column, and a fourth source line SL4 corresponding to an eighth sub-pixel column may extend in an along the bezel 120 defined in the area around the hole.

The number of the source lines SL1, SL2, SL3, and SL4 extending in and the along the bezel 120 defined in the area around the hole may be smaller than the total number of source lines disposed in the first pixel array 130.

Moreover, the first source line SL1 to the fourth source line SL4 extending along and in the bezel 120 defined in the area around the hole may extend in the vertical direction and thus may be disposed in the second pixel array 140.

Each of the first source line SL1 to the fourth source line SL4 in the second pixel array 140 shares sub-pixels in different columns. In one example, in the second pixel array 140, each of the first source line SL1 to the fourth source line SL4 shares sub-pixels corresponding to the same color among sub-pixels in different columns.

Specifically, the source lines extending from the bezel 120 defined in the area around the hole to the second pixel array 140 may include the first source line SL1 corresponding to the blue color, the second source line SL2 corresponding to the red color, the third source line SL3 corresponding to the green color, and the fourth source line SL4 corresponding to the green color.

In the second pixel array 140, the first source line SL1 is connected to sub-pixels B of first and fifth columns corresponding to the blue color in the second pixel array 140. The second source line SL2 is connected to sub-pixels R of third and seventh columns corresponding to the red color. The third source line SL3 is connected to sub-pixels G of a second column and a sixth column corresponding to the green color. The fourth source line SL4 is connected to sub-pixels G of a fourth column and an eighth column corresponding to the green color.

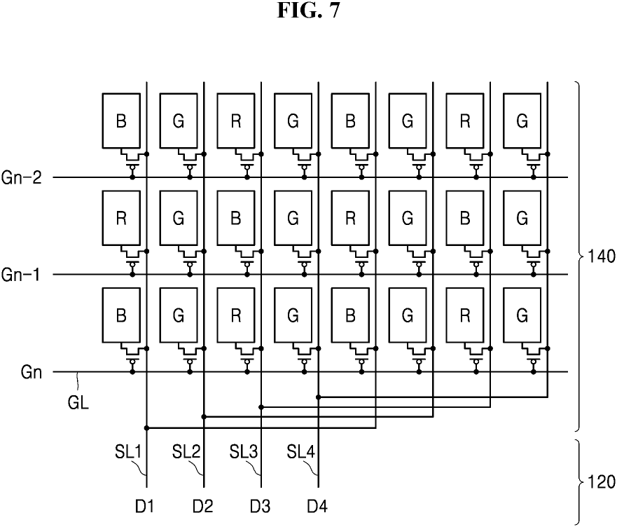

FIG. 7 is a circuit diagram of the display panel 100 corresponding to the 'C' area of FIG. 4.

Referring to FIG. 7, the first source line SL1 to the fourth source line SL4 extending in and along the bezel 120 defined in the area around the hole may extend in the vertical direction so as to be disposed in the second pixel array 140.

The second pixel array 140 includes the first source line SL1 to the fourth source line SL4 extending in the vertical direction, gate lines extending in the horizontal direction, and sub-pixels R, G, and B respectively disposed in areas where the first source line SL1 to the fourth source line SL4 and the gate lines intersect each other.

The first source line SL1 to the fourth source line SL4 may transmit a first source signal to a fourth source signal D1 to D4 to the corresponding sub-pixels R, G, and B, and the plurality of gate lines GL may provide a plurality of gate signals Gn-2, Gn-1, and Gn to a gate terminal of the driving transistor. The driving transistor of the sub-pixel may provide the first source signal to the fourth source signal D1 to D4 to the light-emitting element in response to the gate signals Gn-2, Gn-1, and Gn.

The sub-pixels R, G, and B of the columns disposed in the second pixel array 140 share one of the first source line SL1 to the fourth source line SL4.

In one example, the sub-pixels in the columns corresponding to the same color share the same source line. For example, the source lines extending from the bezel 120 may include the first source line SL1 corresponding to the blue color, the second source line SL2 corresponding to the green color, the third source line SL3 corresponding to the red color, and the fourth source line SL4 corresponding to the green color.

The sub-pixels B of the first column and the fifth column corresponding to the blue color may be connected to the first source line SL1. The sub-pixels G of the second column and the sixth column corresponding to the green color may be connected to the second source line SL2. The sub-pixels R of the third column and the seventh column corresponding to the red color may be connected to the third source line SL3. The sub-pixels G of the fourth and eighth columns corresponding to the green color may be connected to the fourth source line SL4.

According to aspects, reducing the number of the source lines SL extending in and along the bezel 120 defined in the area around the hole 110 may allow the width of the bezel 120 defined in the area around the hole to be reduced. Moreover, the source line SL extending from the bezel 120 defined in the area around the hole 110 shares the sub-pixels corresponding to the same color in the different columns such that the image quality may be maintained. Moreover, reducing the width of the bezel 120 defined in the area around the hole 110 may lead to improvement of the immersion in the image displayed on the display panel 100.

A first aspect of the present disclosure provides a display panel 100 having a hole 110 defined therein, where the display panel includes a first pixel array 130 including source lines SL and sub-pixels R, G, and B; a bezel 120 defined in an area around the hole, wherein at least one SL1, SL2, SL3, and SL4 of the source lines of the first pixel array extends in and along the bezel; and a second pixel array 140 including sub-pixels and the at least one source line SL1, SL2, SL3, and SL4 extending along and in the bezel 120 defined in the area around the hole and into the second pixel array 140.

In one aspect of the first aspect, a number of the at least one source line SL1, SL2, SL3, and SL4 extending in and along the bezel 120 defined in the area around the hole 110 is smaller than a number of the source lines of the first pixel array 130.

In one aspect of the first aspect, in the second pixel array 140, the at least one source line SL1, SL2, SL3, and SL4 shares sub-pixels in different columns.

In one aspect of the first aspect, in the second pixel array 140, the at least one source line SL1, SL2, SL3, and SL4 shares sub-pixels corresponding to the same color among sub-pixels in different columns.

In one aspect of the first aspect, at least two SL1, SL2, SL3, and SL4 of the source lines of the first pixel array 130 extend in and along the bezel 120 defined in the area around the hole 110.

In one aspect of the first aspect, at least two SL1, SL2, SL3, and SL4 of the source lines of the first pixel array 130 includes: a first source line SL1 corresponding to a blue color, a second source line SL2 corresponding to a green color, a third source line SL3 corresponding to a red color, and a fourth source line SL4 corresponding to a green color.

In one aspect of the first aspect, the first source line SL1 is connected to sub-pixels B corresponding to the blue color of a first column and a fifth column in the second pixel array 140, the second source line SL2 is connected to sub-pixels G corresponding to the green color of a second column and a sixth column in the second pixel array 140, the third source line SL3 is connected to sub-pixels R corresponding to the red color of a third column and a seventh column in the second pixel array 140, and the fourth source line SL4 is connected to sub-pixels G corresponding to the green color of a fourth column and an eighth column in the second pixel array 140.

In one aspect of the first aspect, in the first pixel array 130, the source lines extend in a vertical direction, wherein the bezel 120 defined in the area around the hole 110 is disposed between the first pixel array 130 and the second pixel array 140, wherein the at least one of the source lines of the first pixel array 130 extends along and in the bezel 120 defined in the area around the hole 110.

A second aspect of the present disclosure provides a display device 1000 comprising: a display panel 100 having a hole 110 defined therein; and a source driver for providing a source signal to the display panel, wherein the display panel includes: a first pixel array 130 including source lines for transmitting the source signal and sub-pixels for emitting light based on the source signal; a bezel 120 defined in an area around the hole 110, wherein at least one of the source lines of the first pixel array 130 extends in and along the bezel 120; and a second pixel array 140 including sub-pixels and the at least one source line SL1, SL2, SL3, and SL4 extending along and in the bezel 120 defined in the area around the hole 110 and into the second pixel array 140.

In one aspect of the second aspect, a number of the at least one source line SL1, SL2, SL3, and SL4 extending in and along the bezel 120 defined in the area around the hole 110 is smaller than a number of the source lines of the first pixel array 130.

In one aspect of the second aspect, in the second pixel array 140, the at least one source line SL1, SL2, SL3, and SL4 shares sub-pixels in different columns.

In one aspect of the second aspect, in the second pixel array 140, the at least one source line SL1, SL2, SL3, and SL4 shares sub-pixels corresponding to the same color among sub-pixels in different columns.

In one aspect of the second aspect, at least two SL1, SL2, SL3, and SL4 of the source lines of the first pixel array 130 extend in and along the bezel 120 defined in the area around the hole 110.

In one aspect of the second aspect, at least two SL1, SL2, SL3, and SL4 of the source lines of the first pixel array 130 includes: a first source line SL1 corresponding to a blue color, a second source line SL2 corresponding to a green color, a third source line SL3 corresponding to a red color, and a fourth source line SL4 corresponding to a green color.

In one aspect of the second aspect, the first source line SL1 is connected to sub-pixels B corresponding to the blue color of a first column and a fifth column in the second pixel array 140, the second source line SL2 is connected to sub-pixels G corresponding to the green color of a second column and a sixth column in the second pixel array 140, the third source line SL3 is connected to sub-pixels R corresponding to the red color of a third column and a seventh column in the second pixel array 140, and the fourth source line SL4 is connected to sub-pixels G corresponding to the green color of a fourth column and an eighth column in the second pixel array 140.

A third aspect of the present disclosure provides a display panel 100 having a hole 110 defined therein, the display panel comprising: a first pixel array 130; a second pixel array 140; and a bezel 120 defined in an area around the hole 110, wherein the bezel 120 is formed between the first pixel array 130 and the second pixel array 140, wherein at least one of source lines disposed in the first pixel array 130 and extending in a vertical direction extends along and in the bezel 120 defined in the area around the hole 110.

In one aspect of the third aspect, the at least one source line SL1, SL2, SL3, and SL4 extending in and along the bezel 120 defined in the area around the hole 110 extends into the second pixel array 140 in the vertical direction.

In one aspect of the third aspect, a number of source lines disposed in the second pixel array 140 is smaller than a number of the source lines disposed in the first pixel array 130.

In one aspect of the third aspect, in the second pixel array 140, each of the at least one source line SL1, SL2, SL3, and SL4 shares sub-pixels in different columns.

In one aspect of the third aspect, in the second pixel array 140, each of the at least one source line SL1, SL2, SL3, and SL4 shares sub-pixels corresponding to the same color among sub-pixels in different columns.

In one example, the aspects illustrate that the hole is formed in an upper area of the display panel. However, the disclosure is not limited thereto. In another example, a hole may be formed at an edge or in a lower area of the display panel. The number of the source lines extending in and along the bezel defined in the area around the hole may be smaller than the number of the source lines disposed in the first sub-pixel array, so that the bezel width may be reduced.

Further, the aspects exemplify that the source line extends in and along the bezel defined in the area around the hole. However, the disclosure is not limited thereto. According to an aspect, a gate line may extend in and along the bezel defined in the area around the hole. In one example, when the source driver is installed at each of both opposing sides of the display panel and the gate driver is installed at an end in the -Y-axis direction of the display panel and the gate line extends vertically, the number of the gate lines extending in and along the bezel defined in the area around the hole may be smaller than the number of the gate lines disposed in the sub-pixel array.

Further, according to the present disclosure, a sensing line may be disposed in the bezel defined in the area around the hole. In one example, in the organic light-emitting display device, the sensing line for sensing characteristics of the sub-pixels of the display panel may extend in and along the bezel defined in the area around the hole.

Although the aspects of the present disclosure have been described above in more detail with reference to the accompanying drawings, the present disclosure is not necessarily limited to the aspects, and various modifications may be made within the scope that does not deviate from the technical spirit of the present disclosure. Therefore, the aspects as disclosed in the present disclosure are to illustrate the disclosure rather than limiting the technical idea of the present disclosure, and the scope of the technical idea of the present disclosure is not limited to the aspects. Therefore, it should be understood that the aspects as described above are illustrative in all respects and not restrictive. The protective scope of the present disclosure should be interpreted based on the claims, and all technical ideas within the scope equivalent thereto should be construed as being included in the scope of the present disclosure.

What is claimed is:

1. A display panel having a hole, comprising:
a first pixel array including a plurality of source lines and a plurality of sub-pixels;
a bezel defined around the hole and at least one source line among the plurality of source lines in the first pixel array extends along the bezel; and
a second pixel array including a plurality of sub-pixels,
wherein the at least one source line extended along the bezel extends to the second pixel array.

2. The display panel of claim 1, wherein a number of the at least one source line extending along the bezel is smaller than a number of the plurality of source lines in the first pixel array.

3. The display panel of claim 1, wherein the at least one source line of the second pixel array shares sub-pixels in different columns.

4. The display panel of claim 1, wherein the at least one source line of the second pixel array shares sub-pixels corresponding to a same color among sub-pixels in different columns.

5. The display panel of claim 1, wherein at least two of the source lines of the first pixel array extend along the bezel.

6. The display panel of claim 5, wherein at least two of the source lines of the first pixel array includes a first source line corresponding to a blue color, a second source line corresponding to a green color, a third source line corresponding to a red color, and a fourth source line corresponding to a green color.

7. The display panel of claim 6, wherein the first source line is connected to sub-pixels corresponding to the blue color of a first column and a fifth column of the second pixel array,
the second source line is connected to sub-pixels corresponding to the green color of a second column and a sixth column of the second pixel array,
the third source line is connected to sub-pixels corresponding to the red color of a third column and a seventh column of the second pixel array, and
the fourth source line is connected to sub-pixels corresponding to the green color of a fourth column and an eighth column of the second pixel array.

8. The display panel of claim 1, wherein the plurality of source lines in the first pixel array extend in a vertical direction,
wherein the bezel is disposed between the first pixel array and the second pixel array, and
wherein the at least one of the source lines of the first pixel array extends along and in the bezel.

9. A display device comprising:
a display panel having a hole; and
a source driver providing a source signal to the display panel;
wherein the display panel includes:
a first pixel array including a plurality of source lines for transmitting the source signal and a plurality of sub-pixels for emitting light based on the source signal;
a bezel defined around the hole and at least one source line of the plurality of source lines in the first pixel array extends along the bezel;
a second pixel array including sub-pixels and the at least one source line extending along the bezel and extending to the second pixel array.

10. The display device of claim 9, wherein a number of the at least one source line extending along the bezel is smaller than a number of the plurality of source lines of the first pixel array.

11. The display device of claim 9, wherein the at least one source line of the second pixel array shares sub-pixels in different columns.

12. The display device of claim 9, wherein the at least one source line of the second pixel array shares sub-pixels corresponding to a same color among sub-pixels in different columns.

13. The display device of claim 9, wherein at least two of the source lines of the first pixel array extend along the bezel.

14. The display device of claim 13, wherein at least two of the source lines of the first pixel array includes a first source line corresponding to a blue color, a second source line corresponding to a green color, a third source line corresponding to a red color, and a fourth source line corresponding to a green color.

15. The display device of claim 14, wherein the first source line is connected to sub-pixels corresponding to the blue color of a first column and a fifth column in the second pixel array,
the second source line is connected to sub-pixels corresponding to the green color of a second column and a sixth column in the second pixel array,
the third source line is connected to sub-pixels corresponding to the red color of a third column and a seventh column in the second pixel array, and
the fourth source line is connected to sub-pixels corresponding to the green color of a fourth column and an eighth column in the second pixel array.

16. A display panel having a hole, comprising:
a first pixel array;
a second pixel array; and
a bezel defined around the hole between the first pixel array and the second pixel array,
wherein at least one source line disposed in a vertical direction in the first pixel array extends along the bezel.

17. The display panel of claim 16, wherein the at least one source line extending along the bezel extends to the second pixel array in the vertical direction.

18. The display panel of claim 17, wherein a number of source lines disposed in the second pixel array is smaller than a number of the source lines disposed in the first pixel array.

19. The display panel of claim 16, wherein each of the at least one source line in the second pixel array shares sub-pixels in different columns.

20. The display panel of claim 19, wherein each of the at least one source line in the second pixel array shares sub-pixels corresponding to a same color among sub-pixels in different columns.
